(19) United States
(12) Patent Application Publication
(10) Pub. No.: US 2026/0096234 A1
(43) Pub. Date: Apr. 2, 2026

(54) CMOS IMAGE SENSOR AND MANUFACTURING METHOD THEREOF

(71) Applicant: PixArt Imaging Incorporation, Hsinchu (TW)

(72) Inventor: Hsin-Hui Hsu, Hsinchu (TW)

(21) Appl. No.: 18/901,163

(22) Filed: Sep. 30, 2024

(51) Int. Cl. H01L 27/146

(52) U.S. Cl. CPC H10F 39/8057; H10F 39/024; H10F 39/18; H10F 39/8063

(57) ABSTRACT

The present invention provides a CMOS image sensor and a manufacturing method thereof. The CMOS image sensor includes: a plurality of photodiodes configured to convert incident light to electrical signals; a metal grid disposed over the plurality of photodiodes, wherein the metal grid is configured to block parasitic light crosstalk effects between corresponding ones of the plurality of photodiodes; and a plurality of lenses positioned on the metal grid, configured to focus light onto the plurality of photodiodes [symbol] wherein the metal grid includes a plurality of perimeters corresponding to the plurality of openings, and each of the perimeter includes a plurality of frames, wherein the plurality of frames of the corresponding perimeter enclose the corresponding opening in a closed-loop manner; wherein each of the plurality of frames has an aspect ratio greater than 3.

### BACKGROUND OF THE INVENTION

### Field of Invention

The present invention relates to a CMOS image sensor. Particularly, it relates to such CMOS image sensor which can mitigate parasitic light crosstalk effects and improve sensitivity. The present invention also relates to a manufacturing method of the CMOS image sensor.

### Description of Related Art

FIG. 1A shows a top view schematic diagram of a prior art CMOS image sensor 10. FIG. 1B shows a top view schematic diagram of a prior art perimeter 10a of the CMOS image sensor 10. FIG. 1C shows a cross-sectional schematic diagram of the prior art CMOS image sensor 10 along a cut line AA′ shown in FIG. 1A. Referring to FIGS. 1A-1C, the CMOS image sensor 10 includes a plurality of photodiodes 12 arranged in a grid pattern, wherein each photodiode 12 is surrounded by a perimeter 14a to block crosstalk effects between adjacent photodiodes 12. The metal grid 14 is essential in preventing light from entering neighboring photodiodes, which could otherwise cause image blurring.

FIG. 1B shows a top view schematic diagram of a prior art perimeter 14a of the metal grid 14 of the CMOS image sensor 10. The perimeter 14a includes multiple frames 141, which surround a corresponding lens 16. These frames 141 are part of the metal grid 14 and are designed to block unwanted light. When the size of each photodiode 11 is approximately 2 micrometers squared and the width of the frame 14 is about 0.1 micrometers, the image sensor's sensitivity remains within an acceptable range. However, as the size of the photodiode is reduced to 0.5 micrometers squared, while the frame width remains at 0.1 micrometers, the frame blocks approximately 20% of the light, thereby reducing the sensitivity significantly.

FIG. 1C shows a cross-sectional schematic diagram of the prior art CMOS image sensor 10. FIGS. 1A-1C illustrate how the metal grid 14, positioned above the dielectric layers 13 and 15 and photodiodes 12, block light from reaching adjacent photodiodes 12, thereby reducing crosstalk effects. However, due to the increased proportion of the metal grid 12 relative to the shrinking photodiode 12, a significant amount of light is blocked, resulting in decreased sensitivity.

In the prior art shown in FIGS. 1A-1C, a top surface of the frame 141 in the metal grid 12 is flat. When light strikes this flat top surface, a portion of the incident light is reflected away, preventing it from reaching the photodiode 12. This reflection phenomenon results in a reduction of the effective amount of light that can enter the photodiode 12, thereby decreasing the overall sensitivity of the CMOS image sensor. The inability of the reflected light to enter the photodiode means that a certain proportion of the incident light is essentially lost, which negatively impacts the performance of the CMOS image sensor 10, particularly in low-light conditions.

In traditional CMOS image sensor designs, whether using front-side illumination (FSI) or back-side illumination (BSI), a metal grid 14 is employed to block stray light from reaching neighboring pixels. As manufacturing processes advance and photodiode sizes decrease, the challenge lies in minimizing the metal grid's impact on light sensitivity while maintaining its effectiveness in preventing cross-talk.

In view of the above, the present invention proposes a CMOS image sensor and a manufacturing method thereof to overcome the drawbacks in the prior art.

### SUMMARY OF THE INVENTION

From one perspective, the present invention provides a CMOS image sensor, comprising: a plurality of photodiodes configured to convert incident light to electrical signals; a metal grid disposed over the plurality of photodiodes, wherein the metal grid is configured to block parasitic light crosstalk effects between corresponding ones of the plurality of photodiodes; and a plurality of lenses positioned on a plurality of openings of the metal grid, configured to focus light onto the plurality of photodiodes respectively; wherein the metal grid includes a plurality of perimeters corresponding to the plurality of openings, and each of the perimeter includes a plurality of frames, wherein the plurality of frames of the corresponding perimeter enclose the corresponding opening in a closed-loop manner; wherein each of the plurality of frames has an aspect ratio greater than 3.

In one preferred embodiment, the metal grid is formed by two etching process steps, the two etching process steps including: an anisotropic metal etching process step, which etches a metal layer with an anisotropic manner; and an isotropic metal etching process step, which etches a remained part of the metal layer with an isotropic manner after the anisotropic etching process step.

In one preferred embodiment, the remained part of the metal layer includes a plurality of metal bumps and a plurality of metal dices between the plurality of metal bumps all over a dielectric layer above the photodiodes, such that in the isotropic metal etching process step, the metal dices are etched down to the dielectric layer.

In one preferred embodiment, each of the plurality frames includes two sidewalls opposite to each other, wherein each sidewall has a bend, wherein an upper part of the sidewall above the bend is inclined towards a top surface of the frame, and the angle of the upper part of the sidewall and the top surface is larger than 90 degrees and smaller than 180 degrees.

In one preferred embodiment, an area of the top surface of the metal grid is smaller than an area of a bottom surface of the frame.

In one preferred embodiment, the CMOS image sensor is formed by process steps compatible with CMOS device fabrication.

In one preferred embodiment, a frame width of the frame is smaller than one fifth of a photodiode width of the photodiode.

In one preferred embodiment, the top surface of the frame is formed with a sharp shape, such that the top surface is a pointed tip in a cross-sectional view, minimizing the area of the top surface and reducing light reflection.

In one preferred embodiment, a top surface of the frame is flush with an upper dielectric layer disposed above the photodiodes, reducing the risk of light reflection and enhancing light transmission to the photodiodes.

From another perspective, the present invention provides a manufacturing method of a CMOS image sensor, comprising: providing a silicon substrate; forming a plurality of photodiodes in the silicon substrate; forming a metal grid disposed over the plurality of photodiodes, wherein the metal grid is configured to block parasitic light crosstalk effects between corresponding ones of the plurality of photodiodes; and forming a plurality of lenses positioned on a plurality of openings of the metal grid respectively, wherein the plural lenses are configured to focus light onto the plurality of photodiodes; wherein the metal grid includes a plurality of perimeters corresponding to the plurality of openings, and each of the perimeter includes a plurality of frames, wherein the plurality of frames of the corresponding perimeter enclose the corresponding opening in a closed-loop manner; wherein each of the plurality of frames has an aspect ratio greater than 3.

In one preferred embodiment, the step of forming the metal grid disposed over the plurality of photodiodes includes: etching a metal layer with an anisotropic manner; and etching a remained part of the metal layer with an isotropic manner after the anisotropic etching process step.

In one preferred embodiment, the step of etching the remained part of the metal layer after the anisotropic etching process step includes: etching a plurality of metal dices between a plurality of metal bumps down to a dielectric layer, wherein the remained part of the metal layer includes the plurality of metal bumps and the plurality of metal dices between the plurality of metal bumps all over the dielectric layer above the photodiodes.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a top view schematic diagram of a prior art CMOS image sensor 10.

FIG. 1B shows a top view schematic diagram of a prior art perimeter 10a of the CMOS image sensor 10.

FIG. 1C shows a cross-sectional schematic diagram of the prior art CMOS image sensor 10 along a cut line AA′ shown in FIG. 1A.

FIG. 2A shows a top view schematic diagram of an embodiment of a CMOS image sensor according to the present invention.

FIG. 2B shows a top view schematic diagram of an embodiment of a perimeter 24a of the CMOS image sensor 20 according to the present invention along a cut line BB′ shown in FIG. 2A.

FIG. 2C shows a cross-sectional schematic diagram of a CMOS image sensor according to the present invention.

FIGS. 2D-2G shows cross-sectional schematic diagrams of frames of CMOS image sensors according to the present invention.

FIGS. 3A-3I are schematic diagrams showing a manufacturing method of a CMOS image sensor according to the present invention.

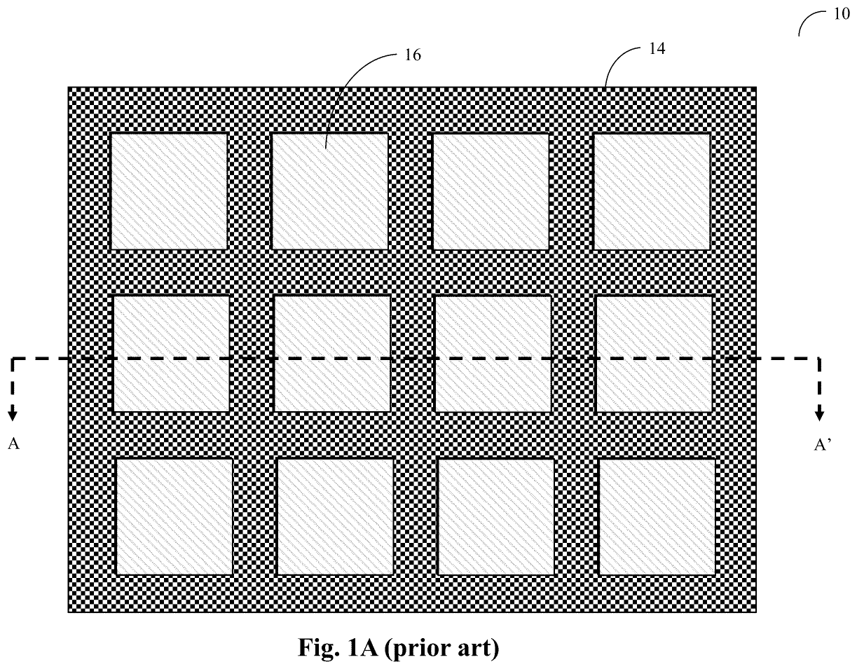

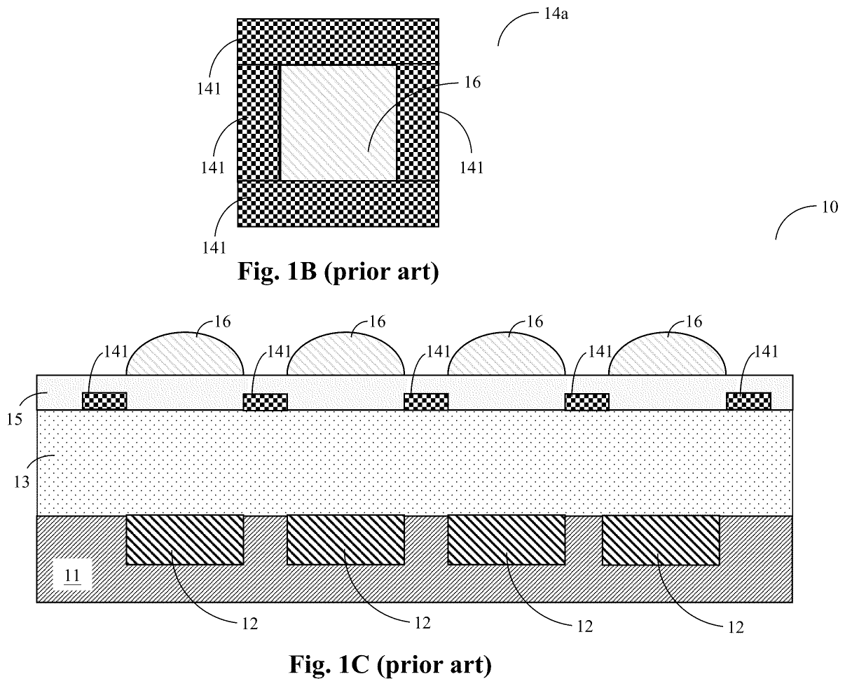

### DESCRIPTION OF THE PREFERRED EMBODIMENTS

The drawings as referred to throughout the description of the present invention are for illustration only, to show the interrelations between the regions and the process steps, but not drawn according to actual scale.

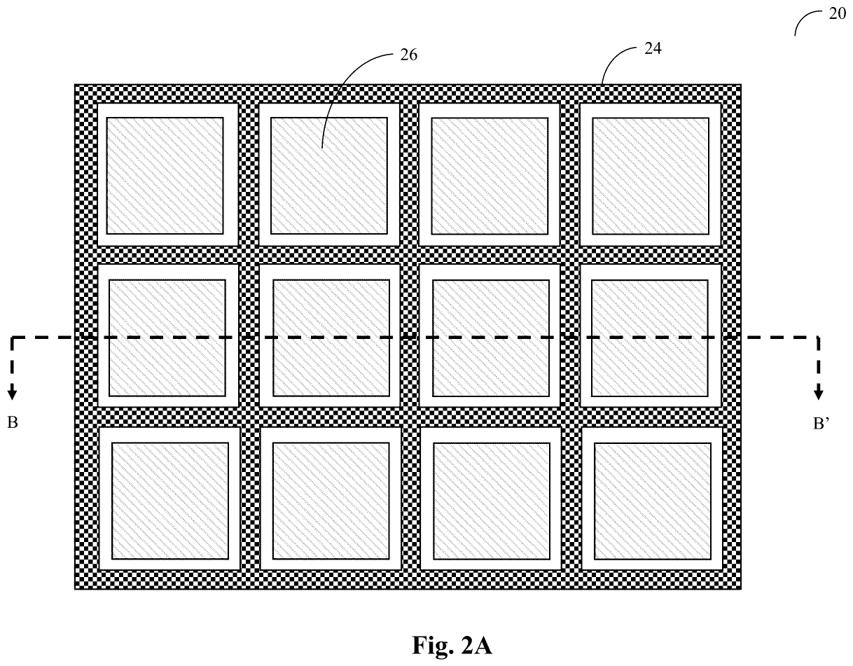

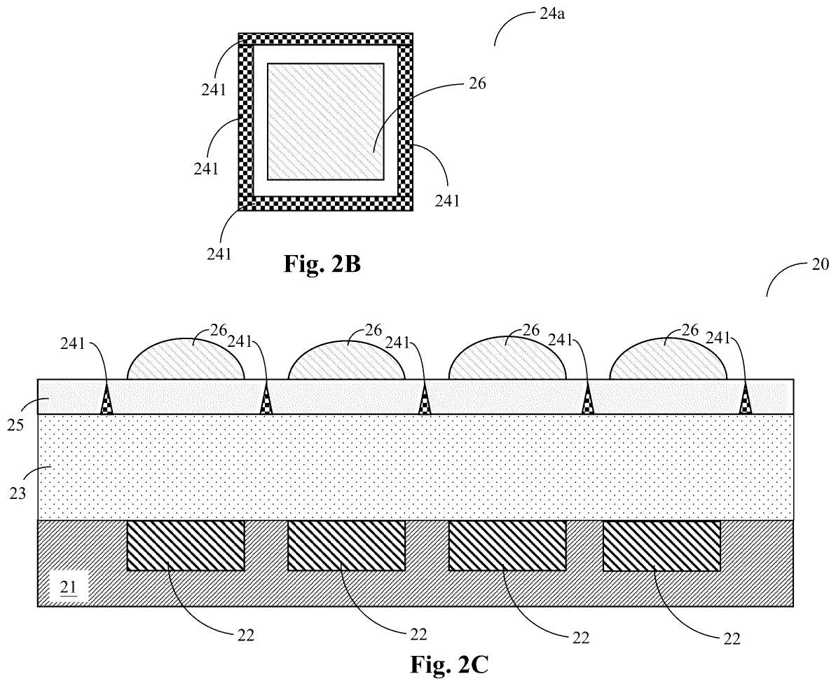

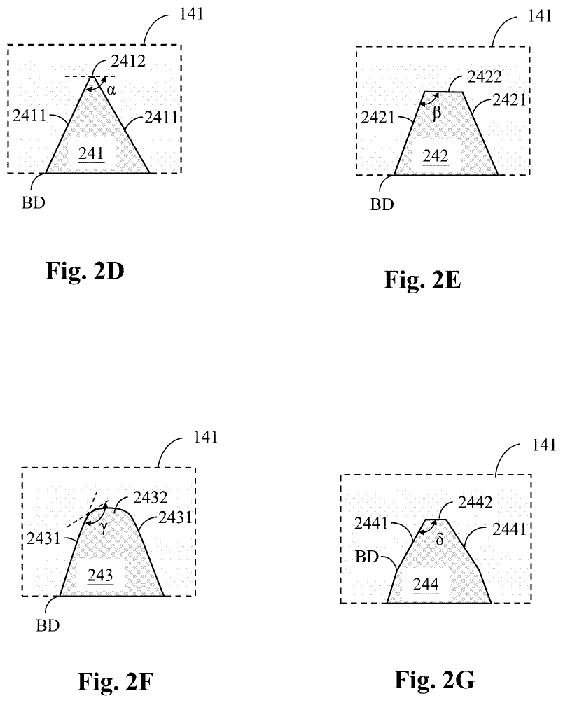

FIG. 2A shows a top view schematic diagram of an embodiment of a CMOS image sensor 20 according to the present invention. FIG. 2B shows a top view schematic diagram of an embodiment of a perimeter of the CMOS image sensor according to the present invention. FIG. 2C shows a cross-sectional schematic diagram of a CMOS image sensor according to the present invention along a cut line BB′ shown in FIG. 2A.

The CMOS image sensor 20 includes plural photodiodes 22, a metal grid 24, and plural lenses 26. The plural photodiodes 22 are configured to convert incident light to electrical signals. The metal grid 24 is disposed over the plural photodiodes 22, wherein the metal grid 24 is configured to block parasitic light crosstalk effects between corresponding ones of the plurality of photodiodes 22. The plural lenses 26 are positioned on plural openings of the metal grid 24 respectively, and are configured to focus light onto the plural photodiodes 22. The metal grid 24 includes plural perimeters 24a corresponding to the plural openings, and each of the perimeter 24a includes plural frames 241, wherein the plural frames 241 of the corresponding perimeter 24a enclose the corresponding opening in a closed-loop manner.

FIGS. 2A-2C illustrate various views of an embodiment of a CMOS image sensor 20 according to the present invention. FIG. 2A shows a top view schematic diagram of the CMOS image sensor 20. The CMOS image sensor 20 comprises a plurality of photodiodes 22 formed in a silicon substrate 21. A metal grid 24 is disposed over the plurality of photodiodes 22 to block parasitic light crosstalk effects between adjacent photodiodes 22. Each opening in the metal grid 24 corresponds to a respective photodiode 22, and a lens 26 is positioned on the corresponding opening to focus incoming light onto the corresponding photodiode 22.

FIG. 2B shows a top view schematic diagram of an embodiment of a perimeter 24a of the CMOS image sensor 20. The perimeter 24a includes a plurality of frames 241 that enclose the corresponding opening in a closed-loop manner. The frames 241 are designed with an aspect ratio greater than 3, meaning that the height of each frame is more than three times its width. This design minimizes the area of the frame's top surface, thereby reducing the amount of light that is reflected away from the photodiodes 22, ensuring more light enters the photodiodes 22.

FIG. 2C shows a cross-sectional schematic diagram of the CMOS image sensor 20 along the cut line AA′ shown in FIG. 2A. In this cross-sectional view, it is evident that the metal grid 24 is formed over a lower dielectric layer 23, which is positioned above the photodiodes 22. The metal grid 24 is formed through two etching process steps. First, an anisotropic metal etching process is used to form an initial structure, i.e., a remained part of a metal layer, with an anisotropic manner. Following this, an isotropic metal etching process is applied to etch the initial structure, i.e., the remained part, with an isotropic manner, resulting in a frame 241 with an upper part that is inclined towards the top surface. The angle of the upper part of the sidewall and the top surface is greater than 90 degrees and less than 180 degrees. Additionally, an area of a top surface of the frame 241 is smaller than an area of its bottom surface, which further enhances light transmission to the photodiodes 22.

The design of the metal grid 24, with its specific aspect ratio and refined structure, enables the CMOS image sensor 20 to maintain high sensitivity by maximizing the amount of light reaching the photodiodes 22 while effectively blocking crosstalk effects between adjacent photodiodes. This structure is compatible with standard CMOS fabrication processes, ensuring it can be integrated into existing manufacturing workflows.

In one embodiment, the remained part of the metal layer includes a plurality of metal bumps and a plurality of metal dices between the plurality of metal bumps all over the lower dielectric layer 23 above the photodiodes 22, such that in the isotropic metal etching process step, the metal dices are etched down to the dielectric layer, will be described in details later.

In one embodiment, the CMOS image sensor 20 is formed by process steps compatible with CMOS device fabrication.

In one embodiment, a frame width of the frame 241 is smaller than one fifth of a photodiode width of the photodiode 22.

FIGS. 2D-2G shows cross-sectional schematic diagrams of frames 241, 242, 243, 244 of CMOS image sensors 20 according to the present invention. FIGS. 2D-2G illustrate various cross-sectional views of different embodiments of the frame of the CMOS image sensor 20 according to the present invention. Each of FIGS. 2D-2G demonstrates a possible configuration for the frame, which can vary in shape while maintaining the functionality according to the present invention.

FIG. 2D shows a cross-sectional view of a frame 241 with a pointed, sharp shape. In this embodiment, the frame 241 includes two sidewalls 2411 opposite to each other. Each sidewall 2411 has a bend BD near the base of the frame 241, where an upper part of the sidewall 2411 above the bend BD is inclined towards the top surface 2412 of the frame. The angle α between the upper part of the sidewall 2411 and the top surface 2412 is larger than 90 degrees and smaller than 180 degrees. An area of the top surface 2412 of the frame 241 is smaller than an area of a bottom surface of the frame 241.

In an alternative embodiment, the top end of the frame 241 can be formed with a sharp shape, where the top surface 2412 is a pointed tip in the cross-sectional view. This design further reduces the area of the top surface of the frame, minimizing the amount of light reflected away and enhancing the sensitivity of the CMOS image sensor 20. The tip structure of the frame 241 is particularly effective in directing incident light towards the photodiodes 22 and reducing undesired reflection.

In one embodiment, the top end of the frame 241 can be designed to be flush with the upper dielectric layer 25. By aligning the top surface 2412 of the frame 241 with the upper dielectric layer 25, the risk of light reflection at the top surface 2412 is reduced, allowing more light to reach the photodiodes 22. This configuration also enables a smoother transition of light through the upper dielectric layer 25, thereby further improving the light sensitivity of the CMOS image sensor 20.

FIG. 2E shows a cross-sectional view of a frame 242 with a trapezoidal shape. Similar to the frame 241, the frame 242 has two sidewalls 2421 opposite to each other, with a bend BD at the base. The upper part of the sidewall 2421 above the bend BD is inclined towards the top surface 2422, forming an angle β that is larger than 90 degrees and smaller than 180 degrees. An area of the top surface 2422 of the frame 242 is smaller than an area of a bottom surface of the frame 242.

FIG. 2F shows a cross-sectional view of a frame 243 with a rounded, dome-like shape. The sidewalls 2431 of the frame 243 also include a bend BD at the base. The upper part of the sidewall 2431 above the bend BD is inclined towards the top surface 2432, with the angle γ between the upper part of the sidewall 2431 and the top surface 2432 being larger than 90 degrees and smaller than 180 degrees. An area of the top surface 2432 of the frame 243 is smaller than an area of a bottom surface of the frame 243.

FIG. 2G shows a cross-sectional view of a frame 244 with a polygonal shape. In this embodiment, the bend BD is positioned higher up on the sidewall 2441, above the base of the frame 244. The upper part of the sidewall 2441 above the bend BD is inclined towards the top surface 2442, forming an angle δ that is larger than 90 degrees and smaller than 180 degrees. An area of the top surface 2442 of the frame 244 is smaller than an area of a bottom surface of the frame 244.

The present invention utilizes isotropic etching to create these frame structures with higher aspect ratios compared to prior art frames 141. By increasing the aspect ratio of the frames, the CMOS image sensor 20 can achieve higher sensitivity. Additionally, the surface area of the top surface 2412, 2422, 2432, 2442 of the frames 241, 242, 243, 244 respectively is reduced, which decreases part of incident light that is reflected away, further improving the sensitivity of the CMOS image sensor 20.

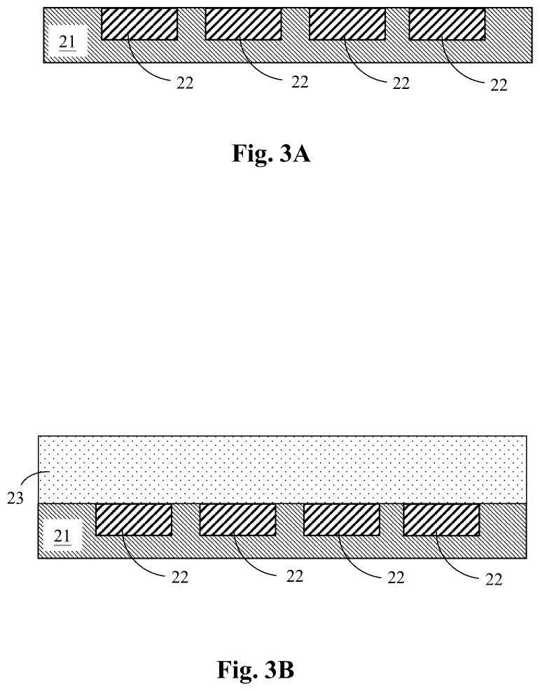

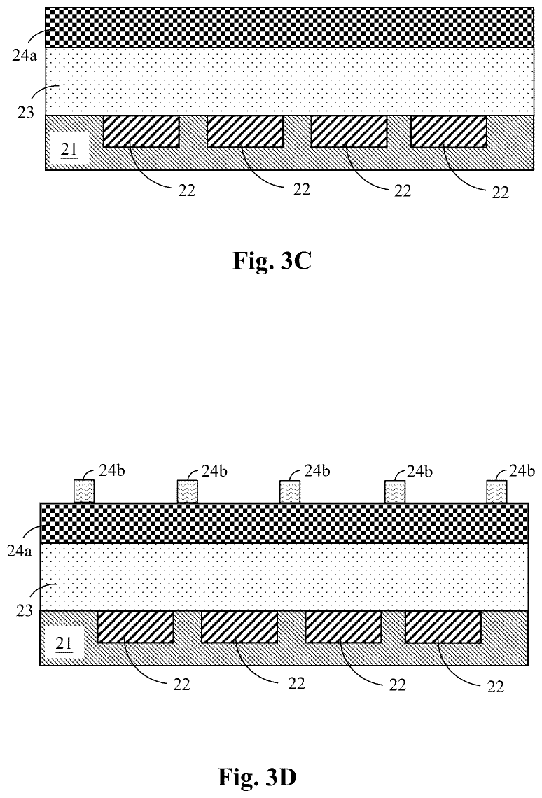

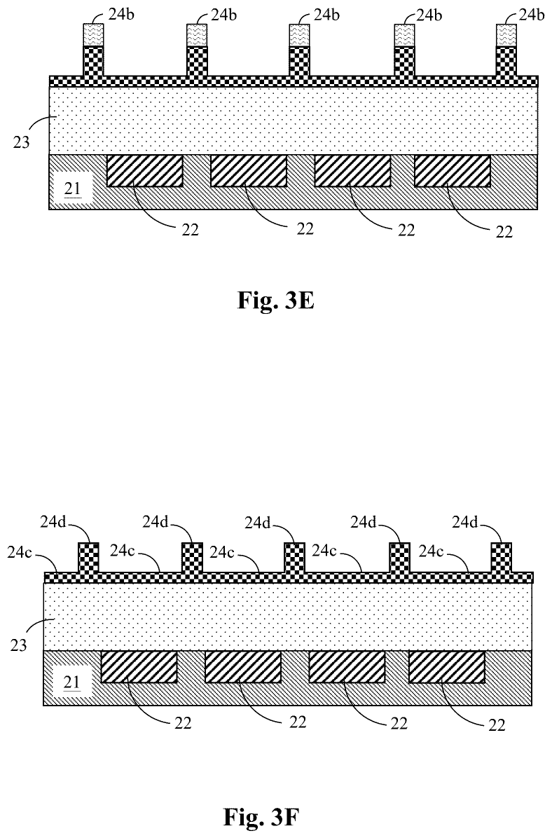

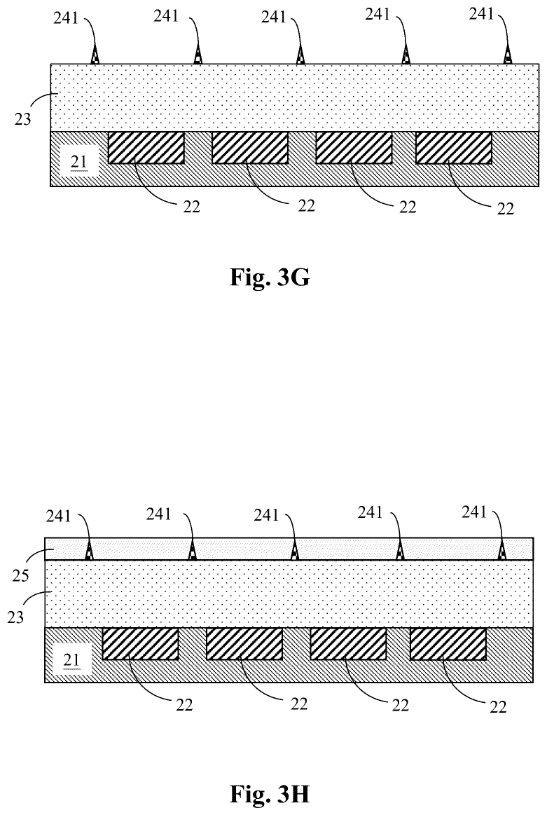

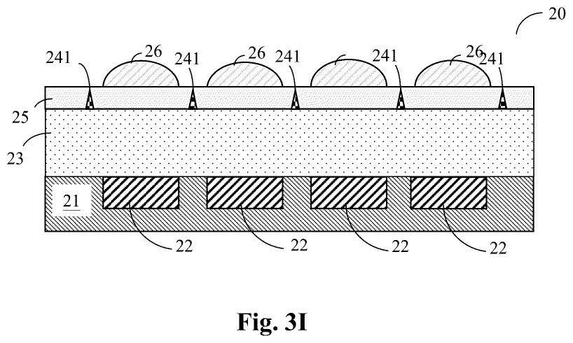

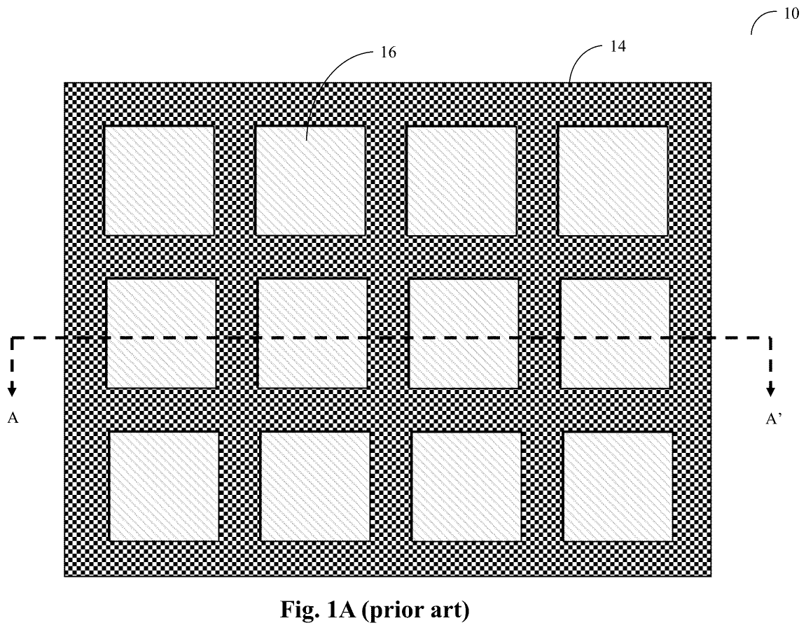

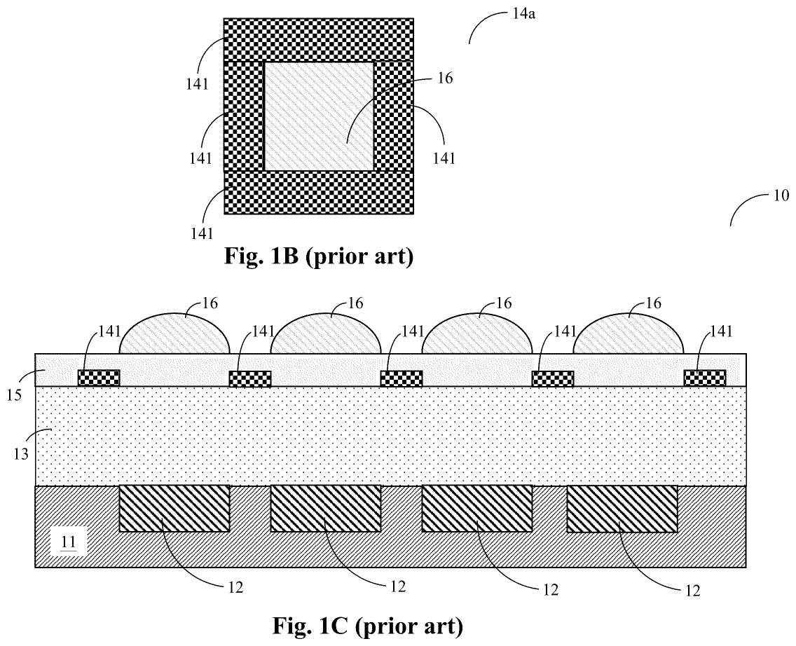

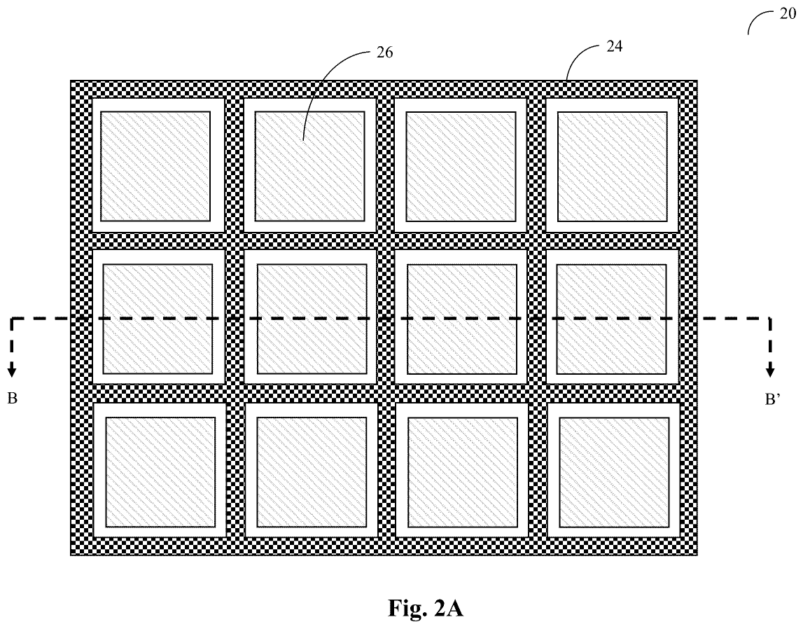

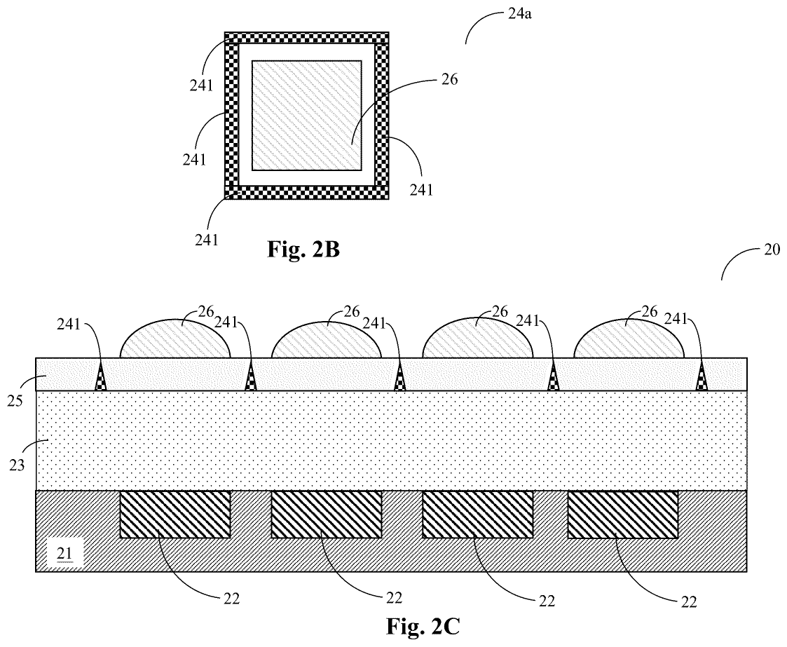

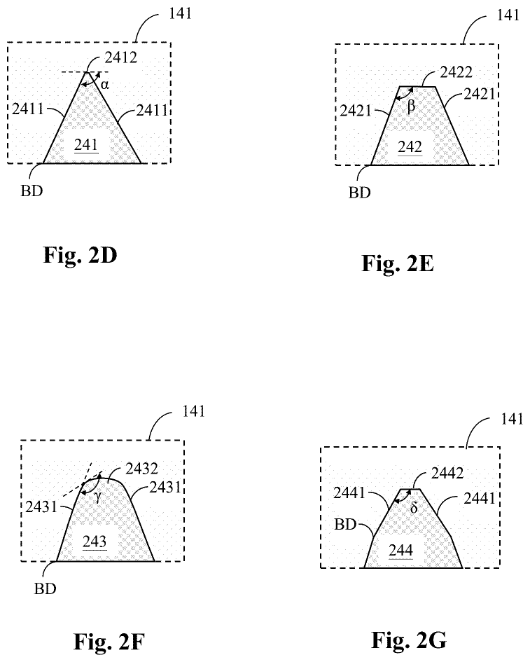

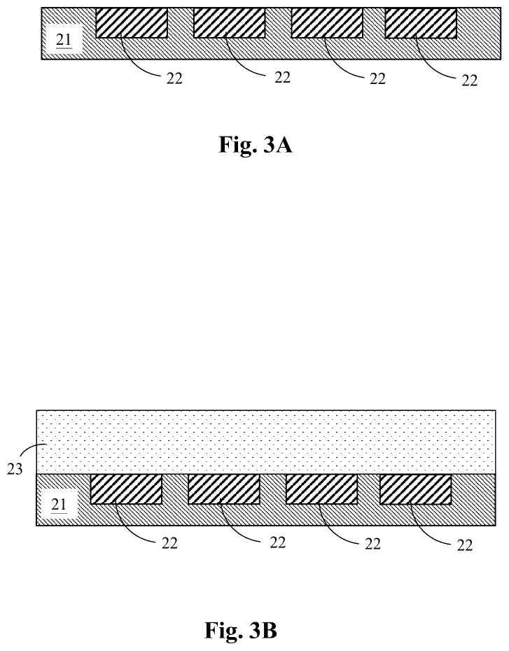

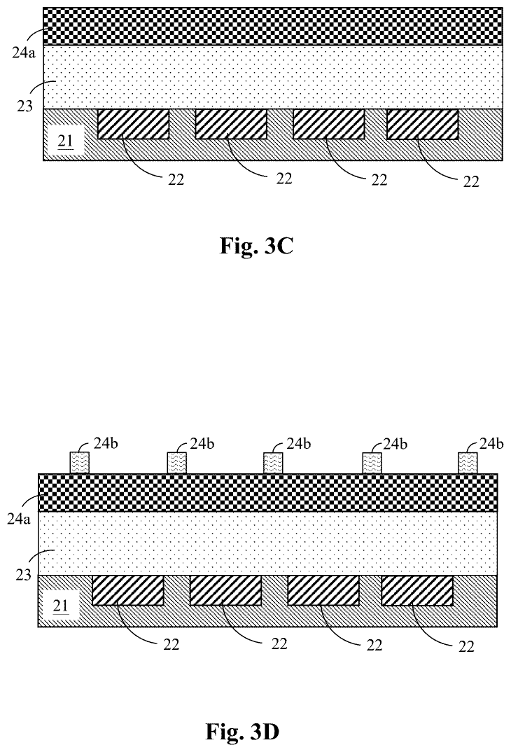

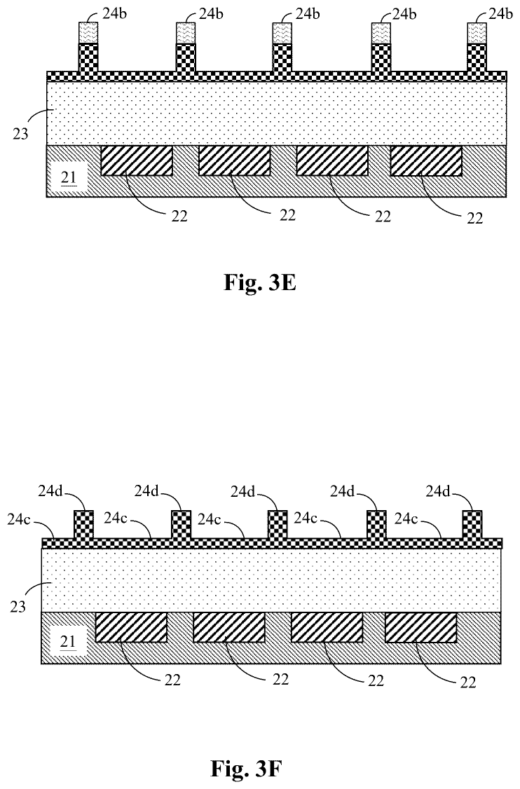

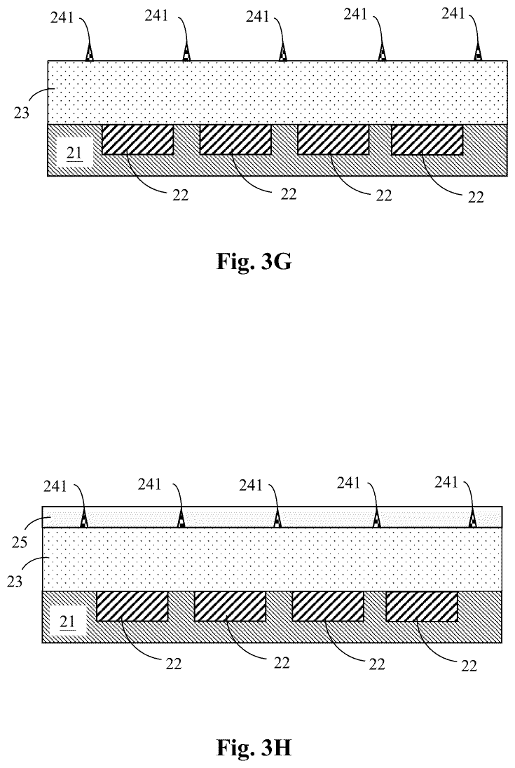

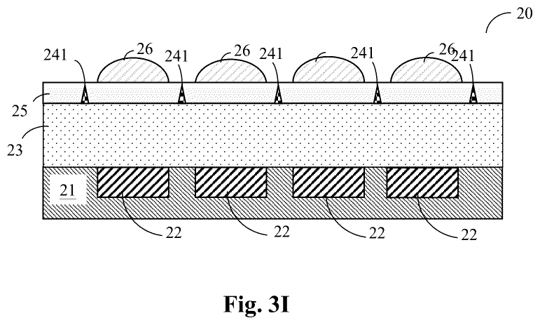

FIGS. 3A-3I are schematic diagrams showing a manufacturing method of the CMOS image sensor 20 according to the present invention. The method is designed to form a metal grid structure over photodiodes in a CMOS image sensor, enhancing its sensitivity and reducing parasitic light crosstalk.

First, as shown in FIG. 3A, a silicon substrate 21 is provided. In one embodiment, the silicon substrate 21 is a P-type silicon substrate. A plurality of photodiodes 22 are formed in the silicon substrate 21. These photodiodes 22 are the primary light-sensitive elements of the CMOS image sensor 20.

Next, as shown in FIG. 3B, a lower dielectric layer 23 over the silicon substrate 21 and the photodiodes 22 is formed. The lower dielectric layer 23 provides electrical insulation and serves as a foundation for subsequent layers.

Then, FIG. 3C illustrates the deposition of a metal layer 24a over the lower dielectric layer 23. The metal layer 24a will eventually be patterned to form the metal grid 24, which is crucial for blocking parasitic light crosstalk between adjacent photodiodes.

Then, as shown in FIG. 3D, FIG. 3D shows the first etching step, where masks 24b, for example but not limited to photoresist, are formed on the metal layer 24a.

Then, as shown in FIG. 3E, the metal layer 24a is etched anisotropically to form initial vertical structures, creating metal bumps that correspond to the metal grid 24.

Then, as shown in FIG. 3F, FIG. 3F shows the result after the anisotropic etching step and the masks 24b removed, where a portion of the metal layer 24a remains in the form of metal bumps 24d and metal dices 24c over the lower dielectric layer 23. These metal dices 24c and metal bumps 24d form the preliminary structure of the metal grid 24, wherein the remained part of the metal layer 24a includes the plurality of metal bumps 24d and the plural metal dices 24c between the plural metal bumps 24d all over the lower dielectric layer 23 above the photodiodes 22.

FIG. 3G illustrates the isotropic etching process step, which etches the metal dices 24c between plural metal bumps 24d down to the lower dielectric layer 23, while further shaping the metal bumps into the desired frame structure. This step ensures that the frames have a high aspect ratio, which is crucial for minimizing the top surface area and reducing light reflection.

FIG. 3H shows the completion of the metal grid 24, with the frames having been formed by the combination of anisotropic and isotropic etching processes and a deposition process for forming an upper dielectric layer 25. The frames 241 are shaped to have bends BD, with their upper parts 2411 inclined towards the top surface 2412, forming an angle α that is larger than 90 degrees and smaller than 180 degrees.

In one embodiment, the top end of the frame 241 can be designed to be flush with the upper dielectric layer 25. By aligning the top surface 2412 of the frame 241 with the upper dielectric layer 25, the risk of light reflection at the top surface 2412 is reduced, allowing more light to reach the photodiodes 22. This configuration also enables a smoother transition of light through the upper dielectric layer 25, thereby further improving the light sensitivity of the CMOS image sensor 20.

FIG. 3H shows the optional step of applying an additional layer over the formed metal grid 24, which can be an organic protective layer or an additional dielectric layer, depending on the specific requirements of the device.

FIG. 3I illustrates the final step of forming a plurality of lenses 26 on the openings of the metal grid 24. These lenses are positioned to focus light onto the photodiodes, ensuring optimal light sensitivity and minimal crosstalk.

The described manufacturing method not only increases the aspect ratio of the metal grid frames but also reduces the area of the top surface of the frames. This design minimizes light reflection and maximizes the sensitivity of the CMOS image sensor 20, while maintaining compatibility with standard CMOS fabrication processes.

The present invention has been described in considerable detail having reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. A CMOS image sensor, comprising:
a plurality of photodiodes configured to convert incident light to electrical signals;
a metal grid disposed over the plurality of photodiodes, wherein the metal grid is configured to block parasitic light crosstalk effects between corresponding ones of the plurality of photodiodes; and
a plurality of lenses positioned on a plurality of openings of the metal grid respectively, configured to focus light onto the plurality of photodiodes [symbol]
wherein the metal grid includes a plurality of perimeters corresponding to the plurality of openings, and each of the perimeter includes a plurality of frames, wherein the plurality of frames of the corresponding perimeter enclose the corresponding opening in a closed-loop manner;
wherein each of the plurality of frames has an aspect ratio greater than 3.

2. The CMOS image sensor of claim 1, wherein the metal grid is formed by two etching process steps, the two etching process steps including:
an anisotropic metal etching process step, which etches a metal layer with an anisotropic manner; and
an isotropic metal etching process step, which etches a remained part of the metal layer with an isotropic manner after the anisotropic etching process step.

3. The CMOS image sensor of claim 2, wherein, the remained part of the metal layer includes a plurality of metal bumps and a plurality of metal dices between the plurality of metal bumps all over a lower dielectric layer above the photodiodes, such that in the isotropic metal etching process step, the metal dices are etched down to the dielectric layer.

4. The CMOS image sensor of claim 2, wherein each of the plurality frames includes two sidewalls opposite to each other, wherein each sidewall has a bend, wherein an upper part of the sidewall above the bend is inclined towards a top surface of the frame, and the angle of the upper part of the sidewall and the top surface is larger than 90 degrees and smaller than 180 degrees.

5. The CMOS image sensor of claim 4, wherein an area of the top surface of the frame is smaller than an area of a bottom surface of the frame.

6. The CMOS image sensor of claim 1, wherein the CMOS image sensor is formed by process steps compatible with CMOS device fabrication.

7. The CMOS image sensor of claim 1, wherein a frame width of the frame is smaller than one fifth of a photodiode width of the photodiode.

8. The CMOS image sensor of claim 5, wherein the top surface of the frame is formed with a sharp shape, such that the top surface is a pointed tip in a cross-sectional view, minimizing the area of the top surface and reducing light reflection.

9. The CMOS image sensor of claim 1, wherein a top surface of the frame is flush with an upper dielectric layer disposed above the photodiodes to reduce risk of light reflection and to enhance light transmission to the photodiodes.

10. A manufacturing method of a CMOS image sensor, comprising:
providing a silicon substrate;
forming a plurality of photodiodes in the silicon substrate;
forming a metal grid disposed over the plurality of photodiodes, wherein the metal grid is configured to block parasitic light crosstalk effects between corresponding ones of the plurality of photodiodes; and
forming a plurality of lenses positioned on a plurality of openings of the metal grid respectively, wherein the plural lenses are configured to focus light onto the plurality of photodiodes;
wherein the metal grid includes a plurality of perimeters corresponding to the plurality of openings, and each of the perimeter includes a plurality of frames, wherein the plurality of frames of the corresponding perimeter enclose the corresponding opening in a closed-loop manner;
wherein each of the plurality of frames has an aspect ratio greater than 3.

11. The manufacturing method of claim 10, wherein the step of forming the metal grid disposed over the plurality of photodiodes includes:
etching a metal layer with an anisotropic manner; and
etching a remained part of the metal layer with an isotropic manner after the anisotropic etching process step.

12. The manufacturing method of claim 11, wherein the step of etching the remained part of the metal layer after the anisotropic etching process step includes: etching a plurality of metal dices between a plurality of metal bumps down to a lower dielectric layer, wherein the remained part of the metal layer includes the plurality of metal bumps and the plurality of metal dices between the plurality of metal bumps all over the lower dielectric layer above the photodiodes.

13. The manufacturing method of claim 11, wherein each of the plurality frames includes two sidewalls opposite to each other, wherein each sidewall has a bend, wherein an upper part of the sidewall above the bend is inclined towards a top surface of the frame, and the angle of the upper part of the sidewall and the top surface is larger than 90 degrees and smaller than 180 degrees.

14. The manufacturing method of claim 12, wherein an area of the top surface of the frame is smaller than an area of a bottom surface of the frame.

15. The manufacturing method of claim 10, wherein the CMOS image sensor is formed by process steps compatible with CMOS device fabrication.

16. The manufacturing method of claim 10, wherein a frame width of the frame is smaller than one fifth of a photodiode width of the photodiode.

17. The manufacturing method of claim 14, wherein the top surface of the frame is formed with a sharp shape, such that the top surface is a pointed tip in a cross-sectional view, minimizing the area of the top surface and reducing light reflection.

18. The manufacturing method of claim 10, further comprising: forming an upper dielectric layer to fill spaces between the plural frames and to cover the plural frames.

19. The manufacturing method of claim 18, wherein a top surface of the frame is flush with the upper dielectric layer disposed above the photodiodes to reduce risk of light reflection and to enhance light transmission to the photodiodes.
